(19) United States
(12) Patent Application Publication
(10) Pub. No.: US 2019/0157241 A1
(43) Pub. Date: May 23, 2019

(54) METHOD OF MANUFACTURING SEMICONDUCTOR DEVICE

(71) Applicant: TOYOTA JIDOSHA KABUSHIKI KAISHA, Toyota-shi (JP)

(72) Inventors: Satoru TAKEMOTO, Okazaki-shi (JP); Kazumi SERIZAWA, Toyota-shi (JP)

(73) Assignee: TOYOTA JIDOSHA KABUSHIKI KAISHA, Toyota-shi (JP)

(21) Appl. No.: 16/193,563

(22) Filed: Nov. 16, 2018

(30) Foreign Application Priority Data
Nov. 17, 2017 (JP) 2017-221548

(51) Int. Cl. H01L 23/00

(52) U.S. Cl. CPC H01L 24/83; H01L 24/32; H01L 24/33; H01L 2224/83238; H01L 23/492; H01L 2224/83801; H01L 2224/32245; H01L 2224/33181; H01L 2924/13055; H01L 2224/831

(57) ABSTRACT

A method of manufacturing a semiconductor device may include interposing a bonding material between an electrode of a semiconductor element and a conductor, the bonding material being a material that is to be melted by heat; melting the bonding material by applying a current to the semiconductor element to cause the semiconductor element to generate heat; and cooling and solidifying the bonding material that is melted by stopping the current.

### CROSS-REFERENCE

This application claims priority to Japanese Patent Application No. 2017-221548, filed on Nov. 17, 2017, the entire contents of which are incorporated herein by reference.

### TECHNICAL FIELD

A technique disclosed herein relates to a method of manufacturing a semiconductor device.

### BACKGROUND

A known method of bonding a conductor to an electrode of a semiconductor element includes: interposing a bonding material, which is a material that is to be melted by heat, between the electrode of the semiconductor element and the conductor; bringing a heating element, which is configured to generate heat by a current flowing therethrongh, into contact with a stack of the semiconductor element, the bonding material and the conductor; applying a current to the heating element to heat and melt the bonding material by the heated heating element; and bonding the semiconductor element and the conductor by the bonding material that is cooled by stopping the current application. Such manufacturing methods are disclosed in Japanese Patent Application Publications No. H05-251504 and No. S59-201084.

### SUMMARY

The disclosure herein discloses a method of manufacturing a semiconductor device that is simpler than the methods of Japanese Patent Application Publications No. H05-251504 and No. S59-201084.

A method of manufacturing a semiconductor device disclosed herein may comprise interposing a bonding material between an electrode of a semiconductor element and a conductor, the bonding material being a material that is to be melted by heat; melting the bonding material by applying a current to the semiconductor element to cause the semiconductor element to generate heat; and cooling and solidifying the bonding material that is melted by stopping the current. Through the melting of the bonding material and cooling and solidifying of the bonding material, the semiconductor element and the conductor are bonded. In this manufacturing method, the semiconductor element and the conductor are bonded by using self-generated heat of the semiconductor element due to its internal resistance. In this manufacturing method, a manufacturing device does not need to include a heating body to heat the bonding material, and thus the semiconductor element and the conductor can be easily bonded.

If temperature of the semiconductor element becomes too high, the semiconductor element may be damaged. Instead of attaching a temperature sensor to the semiconductor element for temperature management, a relation between internal resistance and temperature of the semiconductor element may be identified, and the temperature of the semiconductor element may be regulated based on the relation. In the melting of the bonding material, the temperature of the semiconductor element can be managed without using a temperature sensor.

A transistor is an example of semiconductor element suitable for the manufacturing method disclosed herein. It is possible to cause the transistor to generate heat by applying a half-on voltage to a gate of the transistor and applying a current between a first electrode (a collector or a drain) and a second electrode (an emitter or a source) of the transistor. The half-on voltage is a voltage between a voltage (a threshold voltage) with which a current starts flowing between the first and second electrodes and a voltage (a full conduction voltage) with which the first and second electrodes are completely connected electrically. The application of the half-on voltage brings the transistor into a high-resistance state, and hence the transistor easily generates heat by applying a current between the first and second electrodes.

Meanwhile, when the bonding material melts, resistance between the bonding material and the conductor (or the semiconductor element) sharply decreases. In the melting of the bonding material, the resistance between the bonding material and the conductor (or the semiconductor element) is high until the bonding material is melted, and then sharply decreases when the bonding material melts. Therefore, the timing of melting the bonding material can be identified as a timing when the current, which has been kept flowing with a constant voltage in the semiconductor element, changes. In the manufacturing method disclosed herein, a predetermined constant voltage may be applied to the semiconductor element, and the applying of the predetermined constant voltage may be stopped when the current flowing in the semiconductor element changes. According to this method, the current can be stopped at the timing when the bonding material has been melted.

Details and further improvements of the technique disclosed herein will be described in Detailed Description below.

### BRIEF DESCRIPTION OF DRAWINGS

FIG. 1 is a diagram for describing a manufacturing method of an embodiment.

FIG. 2 is a diagram with a circuit of a semiconductor element added in FIG. 1.

FIG. 3 is a flowchart of the manufacturing method of the embodiment.

FIG. 4 is a diagram for describing a manufacturing method of a first variant.

FIG. 5 is a diagram for describing a manufacturing method of a second variant.

FIG. 6 is a graph illustrating an example of a relation between resistance and temperature of a diode.

FIG. 7 is a graph illustrating an example of a relation between resistance and temperature of a transistor.

FIG. 8 illustrates an example of temporal changes in current flowing in the semiconductor element in a heating and melting process.

### DETAILED DESCRIPTION

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved methods of manufacturing a semiconductor device.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

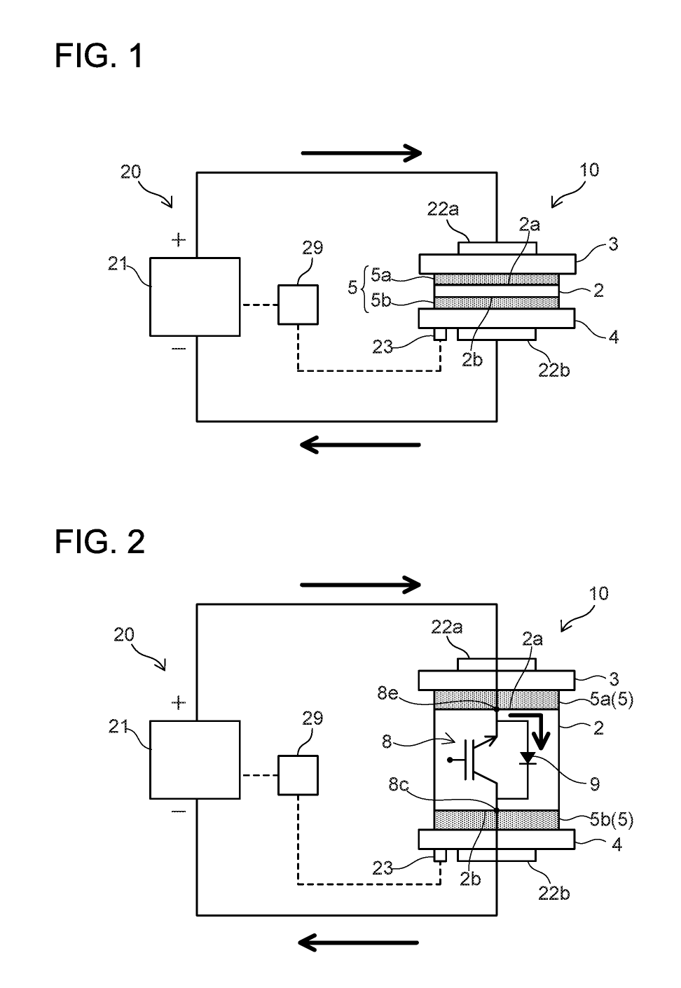

With reference to the drawings, a manufacturing method of an embodiment will be described. FIG. 1 is a diagram for describing the manufacturing method of the embodiment, and schematically depicts a semiconductor device 10 which has not been completed yet and a manufacturing device 20. The semiconductor device 10 is a device that has metal plates 3, 4 bonded respectively to both surfaces of a flat plate-type semiconductor element 2 by solder layers 5. FIG. 1 illustrates a state where the metal plates 3, 4 are not yet bonded. FIG. 2 is a diagram with a circuit of the semiconductor element 2 added in FIG. 1. In FIGS. 1 and 2, the solder layers 5 are shaded with gray for ease of understanding.

As illustrated in FIG. 2, the semiconductor element 2 is a reverse-conducting IGBT (RC-IGBT) in which a transistor 8 and a diode 9 are connected in inverse parallel. The transistor 8 is an isulated gate bipolar transistor (IGBT). An emitter electrode 8e of the transistor 8 is disposed at one surface 2a of the semiconductor element 2, and a collector electrode 8c of the transistor 8 is disposed at another surface 2b of the semiconductor element 2. In the semiconductor element 2, the emitter electrode 8e is connected to an anode of the diode 9, and the collector electrode 8c is connected to a cathode of the diode 9.

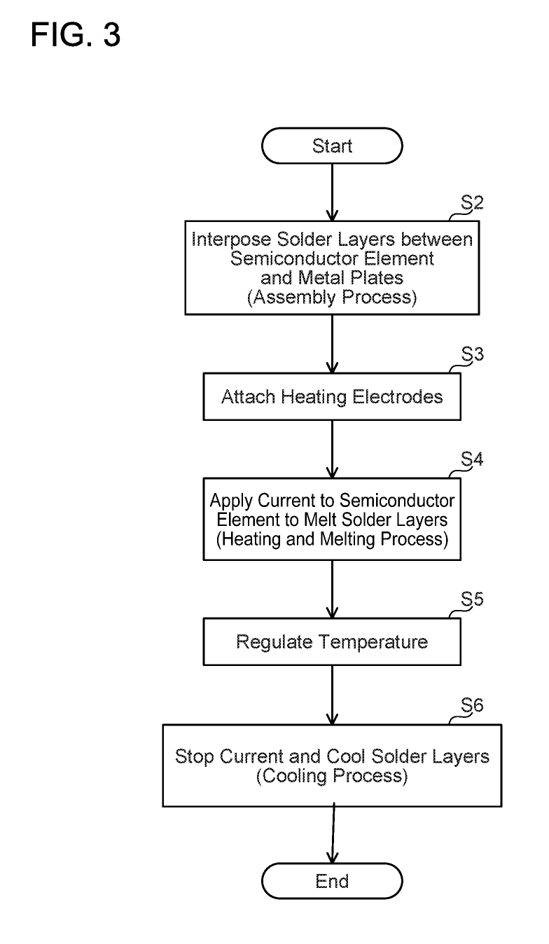

FIG. 3 is a flowchart of a method of manufacturing the semiconductor device 10. With reference to FIGS. 1 and 2, and in accordance with the flowchart in FIG. 3, the manufacturing method will be described.

(Assembly Process)

The metal plates 3, 4, solder layers 5a, 5b, and the semiconductor element 2 are stacked by interposing the solder layer 5a between the metal plate 3 and the emitter electrode 8e disposed at the one surface 2a of the semiconductor element 2, and interposing the solder layer 5b between the metal plate 4 and the collector electrode 8c disposed at the other surface 2b of the semiconductor element 2. (step S2). As is well known, each solder layer 5a, 5b is a bonding material that is to be melted by heat and bonds objects contacting thereto when cooled after melted.

(Heating and Melting Process)

The manufacturing device 20 includes a stabilized power supply 21, heating electrodes 22a, 22b, a temperature sensor 23, and a controller 29. The heating electrode 22a (a positive electrode) is attached to the metal plate 3, and the heating electrode 22b (a negative electrode) is attached to the metal plate 4 (step S3). The temperature sensor 23 is attached to the metal plate 4. The controller 29 activates the stabilized power supply 21 to apply a current to the semiconductor element 2 (the diode 9) via the heating electrodes 22a, 22b and the metal plates 3, 4 (step S4). Each bold arrow in FIGS. 1 and 2 indicates a flow of the current. When the current is applied to the diode 9, the diode 9 generates heat due to its internal resistance. A signal line (a dashed line in the drawing) of the temperature sensor 23 is connected to the controller 29. The controller 29 controls the stabilized power supply 21 based on a temperature measured by the temperature sensor 23 such that a temperature of the semiconductor element 2 does not exceed its heat-tolerable temperature, and regulates the current applied to the semiconductor element 2 (the diode 9). In other words, the controller 29 maintains the temperature of the semiconductor element 2 within a predetermined range (step S5). The predetermined range is a temperature range in which the diode 9 is not damaged and the solder layers 5a, 5b are melted. When a predetermined time has elapsed with the temperature maintained within the predetermined range, the solder layers 5a, 5b are melted. The metal plate 3 and the surface 2a on an emitter electrode 8e's side, which interpose the solder layer 5a therebetween, are bonded by the melted solder layer 5a. The metal plate 4 and the surface 2b on a collector electrode 8c's side, which interpose the solder layer 5b therebetween, are bonded by the melted solder layer 5b.

(Cooling Process)

When the solder layers 5a, 5b have been melted, the controller 29 stops the stabilized power supply 21 to stop the current (step S6). When the current is stopped, the solder layers 5a, 5b are cooled. When cooled, the melted solder layers 5a, 5b are solidified, and the semiconductor element 2 and the metal plates 3, 4 are completely bonded. Through the heating and melting process and the cooling process, the semiconductor element 2 and the metal plates 3, 4 are bonded. Lastly, the heating electrodes 22a, 22b are detached from the semiconductor device 10. As such, the semiconductor device 10 is completed in which the metal plate 3 is bonded to the one surface 2a (the emitter electrode 8e) of the semiconductor element 2, and the metal plate 4 is bonded to the other surface 2b (the collector electrode 8c) of the semiconductor element 2.

After the process of the flowchart in FIG. 3, the semiconductor device 10 is placed in a mold for forming a resin package. A resin package is formed between the metal plates 3, 4 to seal the semiconductor element 2. A semiconductor module (semiconductor device) is thereby completed in which each of the metal plates 3, 4 has one surface thereof exposed from the resin package. The one surface exposed from the resin package means a surface opposite to a surface oriented toward the semiconductor element 2.

The manufacturing method of the embodiment applies a current to the semiconductor element 2 and melts the solder layers 5 by self-generated heat of the semiconductor element 2 due to its internal resistance. The manufacturing method of the embodiment melts the solder layers 5 by using the semiconductor element 2 itself, which is a component of the semiconductor device 10. According to the manufacturing method of the embodiment, there is no need for a dedicated heat-generating device that externally heats the semiconductor element 2, and thus the semiconductor device 10 can be manufactured easily.

(First Variant)

The manufacturing method of the embodiment above melts the solder layers 5 by causing the semiconductor element 2 to generate heat by utilizing the internal resistance of the diode 9, which is included in the semiconductor element 2. In a case where the semiconductor element 2 includes a transistor, the semiconductor element can generate heat by utilizing internal resistance of the transistor.

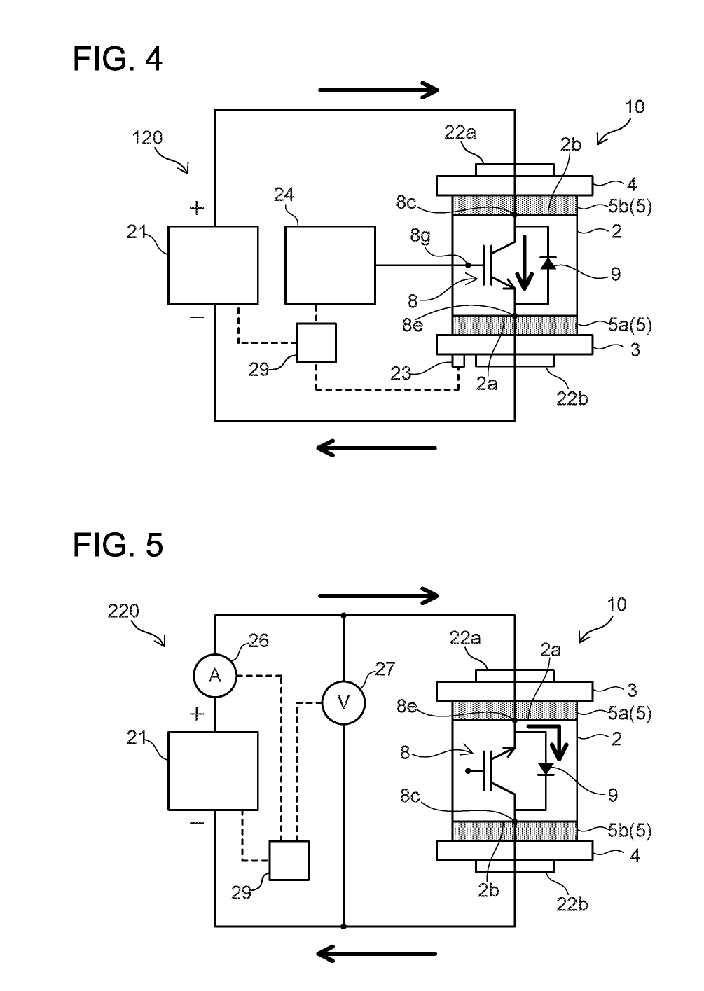

With reference to FIG. 4, a manufacturing method of a first variant will be described. This manufacturing method is a manufacturing method through which the metal plates 3, 4 are bonded to the semiconductor element 2, as in the embodiment. The semiconductor element 2 is identical to that in the embodiment, and includes an inverse parallel circuit of the transistor 8 and the diode 9.

(Assembly Process)

An assembly process is identical to that in the embodiment. In other words, the metal plates 3, 4, the solder layers 5a, 5b, and the semiconductor element 2 are stacked by interposing the solder layer 5a between the metal plate 3 and the emitter electrode 8e disposed at the one surface 2a of the semiconductor element 2, and interposing the solder layer 5b between the metal plate 4 and the collector electrode 8c disposed at the other surface 2b of the semiconductor element 2 (step S2).

(Heating and Melting Process)

A manufacturing device 120 includes the stabilized power supply 21, the heating electrodes 22a, 22b, the temperature sensor 23, a gate driver 24, and the controller 29. The heating electrode 22a (the positive electrode) is attached to the metal plate 4 (on the collector electrode 8c's side), and the heating electrode 22b (the negative electrode) is attached to the metal plate 3 (on the emitter electrode 8e's side) (step S3). The heating electrode 22a (the positive electrode) is connected to the collector electrode 8c of the IGBT 8 via the metal plate 4, and the heating electrode 22b (the negative electrode) is connected to the emitter electrode 8e of the IGBT 8 via the metal plate 3. It should be noted that the heating electrode 22a (the positive electrode) and the heating electrode 22b (the negative electrode) are connected to the collector electrode 8c and the emitter electrode 8e of the transistor 8 in a manner reverse to that in the embodiment above.

The temperature sensor 23 is attached to the metal plate 3. The gate driver 24 is connected to a gate electrode 8g of the transistor 8. Next, the controller 29 activates the gate driver 24 and applies a half-on voltage to the gate electrode 8g of the transistor 8. While applying the half-on voltage to the gate electrode 8g, the controller 29 activates the stabilized power supply 21 and applies a current to the transistor 8 (the semiconductor element 2) (step S4). The half-on voltage is a voltage with which the transistor 8 is turned on halfway. The half-on voltage is a voltage between a voltage (a threshold voltage) with which a current starts flowing between the collector electrode 8c and the emitter electrode 8e, and a voltage (a full conduction voltage) with which both of the electrodes are completely connected electrically. When the half-on voltage is applied between the collector electrode 8c and the emitter electrode 8e, the current flows between the collector electrode 8c and the emitter electrode 8e with high resistance existing between both of the electrodes. The current flows with high resistance existing between both of the electrodes, so the transistor 8 (the semiconductor element 2) easily generates heat.

The controller 29 controls the stabilized power supply 21 based on a temperature measured by the temperature sensor 23 such that the temperature of the semiconductor element 2 does not exceed its heat-tolerable temperature, and regulates the current applied to the semiconductor element 2 (the transistor 8). In other words, the controller 29 maintains the temperature of the semiconductor element 2 within the predetermined range (step S5). When the predetermined time has elapsed with the temperature of the semiconductor element 2 maintained within the predetermined range, the solder layers 5a, 5b are melted. The melted solder layers 5a, 5b bond the metal plates 3, 4 to the semiconductor element 2.

(Cooling Process)

When the solder layers 5a, 5b have been melted, the controller 29 stops the stabilized power supply 21 to stop the current (step S6). At the same time, the gate driver 24 is also stopped. The solder layers 5 are cooled and solidified, and the semiconductor element 2 and the metal plates 3, 4 are thereby completely bonded. The subsequent process is identical to that in the embodiment. Through the heating and melting process and the cooling process, the semiconductor element 2 and the metal plates 3, 4 are bonded. The manufacturing method of the first variant causes the transistor 8 to generate heat by applying a current to the transistor 8 while maintaining the transistor 8 in a half-on state (in a high-resistance state). The manufacturing method of the first variant is suitable to bond a metal plate to a semiconductor element that includes the transistor 8.

(Second Variant)

Each of the embodiment and the first variant manages the temperature of the semiconductor element 2 by using the temperature sensor 23. There is a predetermined relation between internal resistance and temperature of a semiconductor element. A semiconductor device can be manufactured by utilizing this relation for temperature management, without using a temperature sensor.

FIG. 5 is a diagram for describing a manufacturing method of a second variant. The semiconductor device 10, which is a target to be manufactured, is identical to that in the embodiment. The assembly process is also identical to that in the embodiment, and thus the description thereof will be omitted.

(Heating and Melting Process)

A manufacturing device 220 includes the stabilized power supply 21, the heating electrodes 22a, 22b, a current sensor 26, a voltage sensor 27, and the controller 29. The process of attaching the heating electrode 22a (the positive electrode) to the metal plate 3 and attaching the heating electrode 22b (the negative electrode) to the metal plate 4 is identical to that in the embodiment (step S3).

The current sensor 26 measures a current applied to the semiconductor element 2, and the voltage sensor 27 measures a voltage applied between both of the electrodes of the semiconductor element 2. Measurement data of each of the current sensor 26 and the voltage sensor 27 is transmitted to the controller 29.

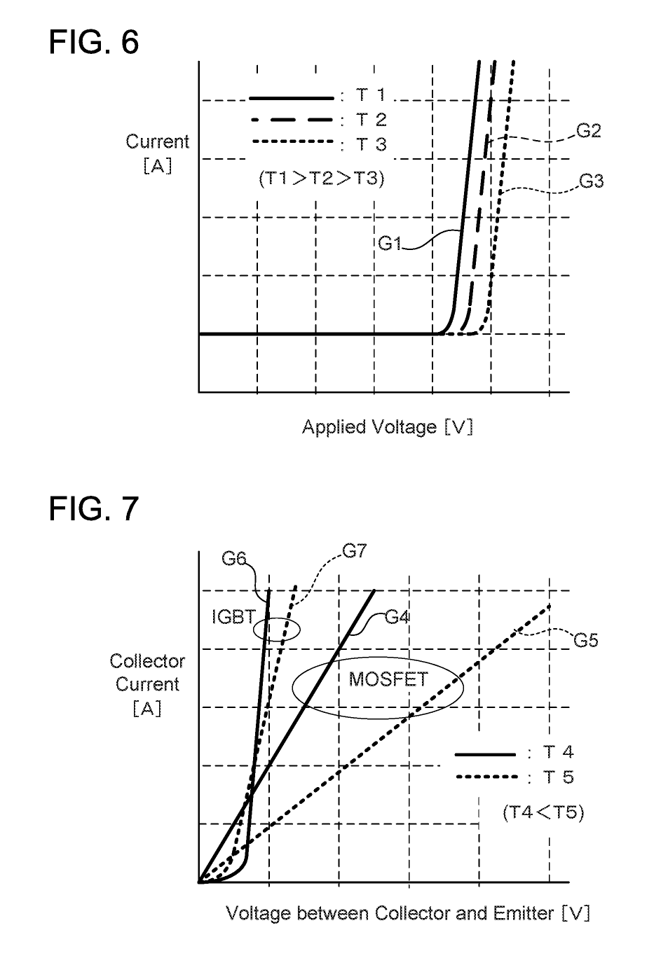

The controller 29 activates the stabilized power supply 21 and applies a current to the semiconductor element 2 (the diode 9) (step S4). When the current is applied to the diode 9, the diode 9 generates heat due to its internal resistance. The controller 29 stores a relation between the internal resistance and the temperature of the diode 9. FIG. 6 illustrates an example of the relation between the internal resistance and the temperature of the diode 9. In FIG. 6, an axis of abscissas indicates voltage applied to the diode 9, and an axis of ordinates indicates current applied to the diode 9. A value obtained by dividing the applied voltage by the current corresponding to the applied voltage corresponds to internal resistance. In other words, the graph in FIG. 6 shows the internal resistance of the diode 9. The diode 9 is characterized in that it takes a very large resistance value until the voltage applied in a forward direction exceeds a predetermined threshold, and the internal resistance sharply decreases once the applied voltage exceeds the threshold.

A graph G1 by a solid line shows changes in the internal resistance when the diode 9 is at a temperature T1. A graph G2 by a dashed line shows changes in the internal resistance at a temperature T2. A graph G3 by a dotted line shows changes in the internal resistance at a temperature T3. Here, the temperature T1 is higher than the temperature T2, and the temperature T2 is higher than the temperature T3 (T1>T2>T3). As is understood from FIG. 6, the lower the temperature is, the higher the voltage that causes a sharp increase in the current (i.e., the voltage that causes a sharp decrease in the internal resistance). The controller 29 estimates the temperature of the diode 9 (the semiconductor element 2) from the relation in the graph in FIG. 6 and the measurement data from each of the current sensor 26 and the voltage sensor 27, and controls the stabilized power supply 21 such that the estimated temperature is maintained within the predetermined range.

When a predetermined time has elapsed with the temperature of the semiconductor element 2 maintained within the predetermined range, the solder layers 5a, 5b are melted. The cooling process is identical to that in the embodiment, and thus the description thereof will be omitted.

In the manufacturing method of the second variant, the relation between the internal resistance and the temperature of the diode 9 (the semiconductor element 2) is identified in advance and stored in the controller 29. The controller 29 regulates the stabilized power supply 21 such that the temperature of the diode 9 (the semiconductor element 2) is maintained within the predetermined range, based on the relation. The manufacturing method of the second variant does not need a temperature sensor, and thus simplifies the manufacturing device.

In the case where the semiconductor element is a transistor as well, there is a specific relation between internal resistance and temperature of the semiconductor element, and the relation may be used for temperature management in the heating and melting process. FIG. 7 illustrates an example of the relation between the internal resistance and the temperature of the transistor. An axis of abscissas indicates voltage applied between the collector and the emitter, and an axis of ordinates indicates collector current. Each of graphs G4, G5 shows a relation in the case of a metal oxide field effect transistor (MOSFET), and each of graphs G6, G7 shows a relation in the case of an insulated gate bipolar transistor (IGBT). Each of the graphs G4, G6 by a solid line shows the relation at a temperature T4, and each of the graphs G5, G7 by a dotted line shows the relation at a temperature T5. The temperature T5 is higher than the temperature T4 (T4<T5).

In FIG. 7 as well, a value obtained by dividing the voltage between the collector and the emitter by its corresponding collector current corresponds to internal resistance of the transistor. With use of the relation in FIG. 7, the manufacturing method through which the metal plate is bonded to the semiconductor element including the transistor can also maintain the temperature of the semiconductor element within the predetermined range in the heating and melting process, without a temperature sensor.

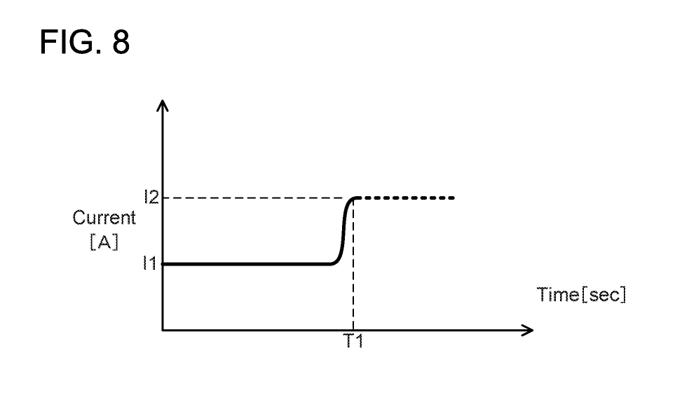

The heating and melting process may include applying a constant voltage to the semiconductor element and stopping the applying of the constant voltage when the current flowing in the semiconductor element sharply changes. Before the solder layers are melted, the solid solder layers and the metal plates (or the semiconductor element) contact each other as solid bodies, and thus contact resistance between them is large. When the solder layers melt, the contact resistance between them sharply decreases. Therefore, when the solder layers melt in the heating and melting process, the current flowing in the semiconductor element sharply increases. FIG. 8 illustrates an example of temporal changes in the current flowing in the semiconductor element in the heating and melting process. In this example, the controller 29 controls the stabilized power supply 21 to keep applying a constant voltage to the semiconductor element in the heating and melting process. In the example in FIG. 8, the current sharply changes from I1 to I2 at a time T1. In other words, it can be detected that the solder layers melt at the time T1. The controller 29 stops the applying of the voltage at the time T1, at which the current changes. As such, the controller 29 can stop the voltage when the solder layers melt.

Some of the features of the technique described in the embodiment will be summarized below. The manufacturing method of the embodiment includes the assembly process, the heating and melting process, and the cooling process. In the assembly process, the solder layer 5a that is not yet melted is interposed between the metal plate 3 and the surface 2a at which the emitter electrode 8e of the semiconductor element 2 is disposed, and the solder layer 5b that is not yet melted is interposed between the metal plate 4 and the surface 2b at which the collector electrode 8c of the semiconductor element 2 is disposed. In the heating and melting process, the controller 29 applies a current to the semiconductor element 2 via the metal plates 3, 4. The semiconductor element 2 generates heat due to the internal resistance. The controller 29 keeps applying the current to the semiconductor element 2 until the solder layers 5 have been melted. When the solder layers 5 have been melted, the controller 29 stops the current. In the cooling process, the solder layers 5 are cooled and solidified by stopping the current. Through the heating and melting process and the cooling process, the semiconductor element 2 and the metal plates 3, 4 are bonded. This manufacturing method melts the solder layers by utilizing the self-generated heat of the semiconductor element due to its internal resistance. A dedicated heating device for heating the solder layers is not required, and thus the metal plates can be bonded to the semiconductor element with ease and at low cost.

Points to be noted relating to the technique described in the embodiment will be mentioned. The manufacturing method of the embodiment has the following advantage over a method in which a bonding material is melted in a high-temperature furnace. In the method of the high-temperature furnace, the bonding material starts to be melted from its periphery. In this case, a void may occur at a center of the bonding material. On the other hand, in the manufacturing method of the embodiment, the bonding material starts to be melted from a portion thereof that is in contact with the semiconductor element, so a void is less likely to occur.

The solder layers 5 in the embodiment correspond to an example of a bonding material. The bonding material used in the manufacturing method of the embodiment simply needs to be of a type that is to be melted by heat, and is not limited to solder. The metal plates 3, 4 in the embodiment correspond to an example of a conductor to be bonded to the semiconductor element. The conductor to be bonded to the semiconductor element may be a conductor block, instead of a metal plate.

One of the emitter electrode 8e and the collector electrode 8c of the transistor 8 corresponds to an example of a first electrode, and the other of them corresponds to an example of a second electrode. The technique disclosed herein is not limited to a semiconductor element that includes a transistor or a diode, and can be applied to various elements having internal resistance.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

What is claimed is:

1. A method of manufacturing a semiconductor device comprising:
interposing a bonding material between an electrode of a semiconductor element and a conductor, the bonding material being a material that is to be melted by heat;
melting the bonding material by applying a current to the semiconductor element to cause the semiconductor element to generate heat; and
cooling and solidifying the bonding material that is melted by stopping the current.

2. The method as in claim 1, wherein
a relation between internal resistance of the semiconductor element and temperature of the semiconductor element is identified, and
the melting of the bonding material comprises regulating the temperature of the semiconductor element to a predetermined range based on the relation.

3. The method as in claim 1, wherein
the semiconductor element is a transistor, and
the melting of the bonding material comprises:
applying a half-on voltage to a gate of the transistor; and
applying a current between a first electrode and a second electrode of the transistor.

4. The method as in claim 1, wherein
the melting of the bonding material comprises:
applying a predetermined constant voltage to the semiconductor element; and
stopping the applying of the predetermined constant voltage when the current flowing in the semiconductor element changes.
